(19) United States
(12) Patent Application Publication
(10) Pub. No.: US 2013/0047913 A1
(43) Pub. Date: Feb. 28, 2013

(54) Method and Apparatus for Doping by Lane in a Multi-Lane Sheet Wafer Furnace

(71) Applicant: Brian Kernan, Newton, MA (US)

(72) Inventor: Brian Kernan, Newton, MA (US)

(73) Assignee: Max Era, Inc., Reno, NV (US)

(21) Appl. No.: 13/220,025

(22) Filed: Aug. 29, 2011

(51) Int. Cl. C30B 15/20; C30B 15/04

(52) U.S. Cl. 117/15; 117/19; 117/208; 117/202

(57) ABSTRACT

A method and apparatus for forming a sheet wafer add material to a crucible having a feed area and a dump area, and melt the material to form a wafer growth area between the feed area and the dump area. The material is added to the feed area and removed through the dump area. The method and apparatus substantially simultaneously draw a plurality of sheet wafers from the growth area, and directly apply dopant to the melted material at the growth area. The dopant thus bypasses the feed area to dope at least a portion of the growth area.

### RELATED APPLICATIONS

This application is related to co-pending U.S. patent application Ser. No. 12/952,288, filed Nov. 23, 2010, attorney docket number 3253/192, naming Brian D Kernan, Gary J Tarnowski, Weidong Huang, Scott Reitsma, and Christine Richardson as inventors, and entitled, “Method of Reducing the Range in Resistivities in Semiconductor Crystalline Sheets Grown in a Multi-lane Furnace,” the disclosure of which is incorporated herein, in its entirety, by reference.

### FIELD OF THE INVENTION

The invention generally relates to sheet wafers and, more particularly, the invention relates to doping sheet wafers.

### BACKGROUND OF THE INVENTION

Crystalline sheet wafers can form the basis of a variety of electronic devices. For example, Evergreen Solar, Inc. of Marlborough, Mass. forms solar cells from sheet wafers, which Evergreen Solar designates STRING RIBBON™ wafers or crystals.

Continuous growth of silicon sheets eliminates the need for slicing bulk produced silicon to form wafers. For example, in one implementation, two filaments of high temperature material are introduced up through the bottom of a crucible, which includes a shallow layer of molten silicon, known as a “melt.” A seed connected to two filaments is lowered into the melt, and then pulled vertically upward from the melt.

A meniscus forms at the interface between the bottom end of the seed and the melt, and the molten silicon freezes into a solid sheet just above the melt. The filaments stabilizes the edges of the growing sheet. U.S. Pat. No. 7,507,291, among other documents, describes a method for growing multiple filament-stabilized crystalline sheets simultaneously in a single crucible. Each sheet grows in a growth region, which is referred to in the art as a “lane” in the multi-lane furnace. This multi-lane wafer fabrication process thus reduces the cost of fabricating wafers when compared to crystalline sheet fabrication in a single-lane furnace.

To convert light to electricity, the wafers must be doped. Doping in a multi-lane furnace, however, presents a number of problems. Among them is uneven and inconsistent doping concentrations across the different lanes.

### SUMMARY OF THE INVENTION

In accordance with one embodiment of the invention, a method and apparatus for forming a sheet wafer adds material to a crucible having a feed area and a remaining area. Specifically, the material is added to the feed area-not the remaining area. The method and apparatus melt the material to form a first growth area and a second growth area, both of which are part of the remaining area. First and second sheet wafers also are drawn (at about the same time) from the first and second growth areas, respectively, and dopant is directly applied to the material at the remaining area. The dopant thus bypasses the feed area to dope at least a portion of the remaining area. In some embodiments, the dopant may diffuse to the feed area.

Various embodiments also apply dopant to material in the feed area of the crucible. Accordingly, this additional dopant bypasses the remaining area to dope the feed area. The method and apparatus may directly apply dopant to the second growth area and not to the first growth area. In this latter case, the directly applied dopant may diffuse from the second growth area and into the first growth area, which is between the feed area and the second growth area. Alternatively, the dopant may be applied to both the first and second growth areas.

Any of a variety of different techniques may directly apply the dopant to the remaining area. In a first implementation, the method and apparatus may directly contact a doped apparatus into the material in the remaining area. For example, the doped apparatus may include a filament that substantially disintegrates after contacting the material, thus releasing the dopant.

Another embodiment releases doped particles from an inkjet apparatus into one or more prespecified portions of the remaining area. Yet another embodiment coats one or more of the filaments of a sheet wafer with dopant. Still other embodiments pass a member (having a dopant) through the material in the remaining area.

Logic may control the amount of dopant applied to the material. To that end, the method and apparatus may measure a quality of at least one of the first and second sheet wafers. Thus, the dopant may be applied as a function of the measured quality. Among other things, the quality may include the resistivity of the at least one of the first and second sheet wafers. The method and apparatus then may change/apply the volume of dopant directly applied as a function of the resistivity.

The method and apparatus also applies to sheet wafer growth systems growing more than two sheet wafers. Moreover, the first and second wafers may be positioned in any of a number of manners. For example, they may be positioned in a side-by-side manner, or face each other.

In accordance with another embodiment, an apparatus for forming a plurality of sheet wafers has a crucible with a feed area and a remaining area, and material inlet for receiving material to be added to the feed area of the crucible. The apparatus also has a wafer puller for drawing a plurality of sheet wafers from the remaining area, and a doping apparatus operably coupled with the crucible. The doping apparatus is configured to directly add dopant to the remaining area, thus bypassing the feed area.

In accordance with other embodiments, a method and apparatus for forming a sheet wafer add material to a crucible having a feed area and a dump area, and melt the material to form a wafer growth area between the feed area and the dump area. The material is added to the feed area and removed through the dump area. The method and apparatus substantially simultaneously draw a plurality of sheet wafers from the growth area, and directly apply dopant to the melted material at the growth area. The dopant thus bypasses the feed area to dope at least a portion of the growth area.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a furnace for growing sheet wafers (“sheet wafer furnace”) that may be configured in accordance with illustrative embodiments of the invention.

FIG. 2 schematically shows a sheet wafer furnace, which is configured in accordance with illustrative embodiments of the invention, with a portion of its housing removed to show its interior.

FIG. 3A schematically shows a crucible that may be configured in accordance with one embodiment of the invention.

FIG. 3B schematically shows the crucible of FIG. 3A during use.

FIG. 4 schematically shows a crucible having a plurality of inkjets that distribute dopant in accordance with illustrative embodiments of the invention.

FIG. 5 schematically shows a crucible having a plurality of additional filament holes for receiving doped filaments that may dope molten material within the crucible.

FIG. 6 schematically a shows a crucible receiving a plurality of doped filaments or similar dopant carriers in accordance with illustrative embodiments of the invention.

FIG. 7 shows a process of substantially simultaneously growing and opening a plurality of wafers in accordance with illustrative embodiments of the invention.

FIG. 8 schematically shows an alternative growth method where plural sheet wafers are grown in a face-to-face manner and doped in accordance with illustrative embodiments of the invention.

### DESCRIPTION OF ILLUSTRATIVE EMBODIMENTS

In illustrative embodiments, a multi-wafer growth furnace precisely controls its doping processes to produce more consistently doped sheet wafers. Consequently, the wafers should have an optimized efficiency. To that end, rather than simply adding dopant at one remote location within the furnace, various embodiments apply some or all of the dopant directly to the lanes in which the wafers grow. This concept may be referred to as “doping by lane.” Details of a number of different embodiments are discussed below.

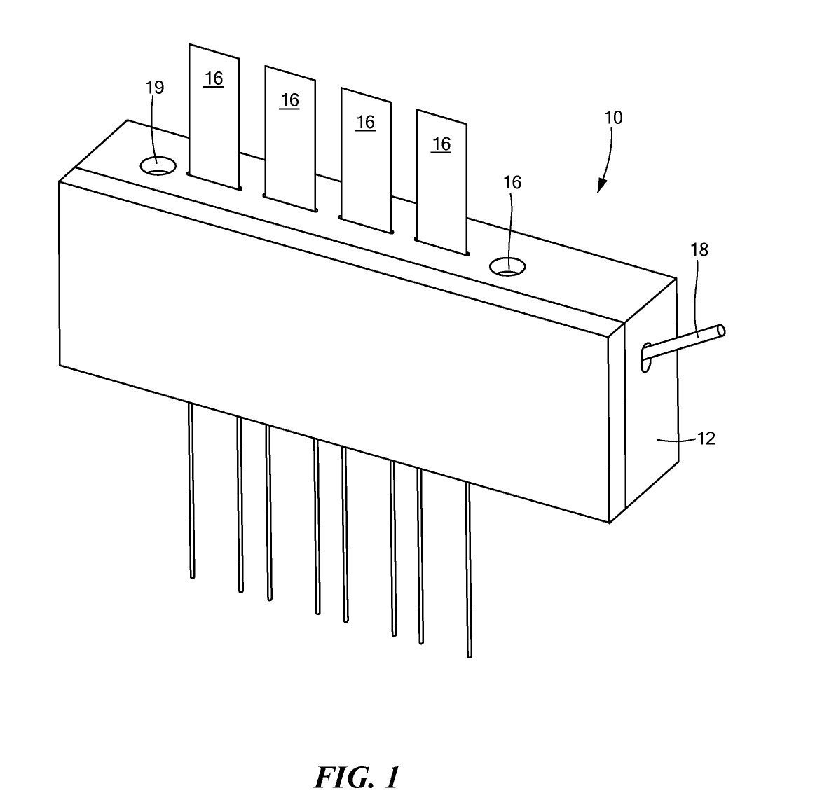

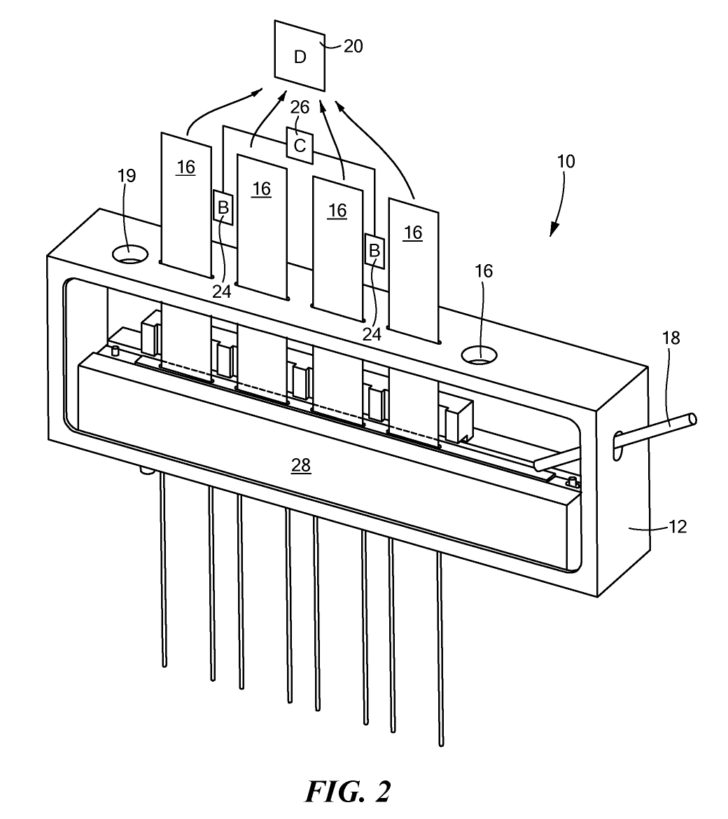

FIG. 1 schematically shows a crystalline sheet wafer growth furnace 10 that may be configured in accordance with illustrative embodiments of the invention. The furnace 10 has, among other things, a housing 12 forming a sealed interior that is substantially free of oxygen (to prevent combustion). Instead of oxygen, the interior has some concentration of another gas, such as argon, or a combination of gasses. The housing interior also contains, among other things, a crucible 14 (shown in FIG. 2 and succeeding figures, discussed below) for containing and melting a material (e.g., silicon) and other components (some of which are discussed below) for substantially simultaneously growing four silicon crystalline sheet wafers 16, or sheet wafers 16, from the melted material.

The sheet wafers 16 growing in FIG. 1 are known in the art as “filament sheet wafers.” For example, the filament sheet wafers 16 may be similar to those known as STRING RIBBON wafers, which are distributed by Evergreen Solar, Inc. of Marlboro, Mass. The sheet wafers 16 thus may be formed from any of a wide variety of crystal types, such as multi-crystalline, single crystalline, polycrystalline, microcrystalline or semi-crystalline. A feed inlet 18 in the housing 12 provides a means for directing silicon feedstock to the interior crucible 14, while an optional window 19 permits inspection of the interior components.

It should be noted that discussion of silicon sheet wafers 16 is illustrative. For example, the sheet wafers 16 may be formed from a material other than silicon, or a combination of silicon and some other material. As another example, illustrative embodiments may form doped non-crystalline sheet wafers 16. Further, while illustrative embodiments of the invention are described with respect to a furnace 10 with four sub-growth regions (“lanes”) with the sheets generally parallel to each other in a single line, other embodiments may employ more growth lanes or fewer growth lanes, and/or the disposition of the growth lanes with respect to each other may differ.

FIG. 2 schematically shows a partially cut away view of the crystalline sheet wafer growth furnace 10 shown in FIG. 1. This view also shows, among other things, a wafer/crystal puller system 20 that substantially simultaneously draws each of the four sheet wafers 16 upwardly from the melt, and a feedback system 22 for controlling melt doping as a function of the wafer resistance. As discussed in greater detail below, this feedback system 22 uses a resistance detector 24 to determine the resistance of a given sheet wafer 16, and a controller 26 that controls the amount of dopant added to the melt.

Any number of different devices can serve the functions of resistance detector 24 and controller 26. For example, one or more eddy current detectors could serve as resistance detectors 24, while a logic element, such as a microprocessor, digital signal processor, application specific integrated circuit, circuit module, or combination of components can serve as the controller 26. Each lane may have an individual resistance detector 24 and controller 26. Alternatively, the various lanes may share resistance detectors 24 and/or controllers 26. The feedback system 22 could be positioned a short distance above the furnace 10 (i.e., outside of the housing 12), or inside the housing 12 if the equipment is robust enough to withstand the high temperatures within the furnace.

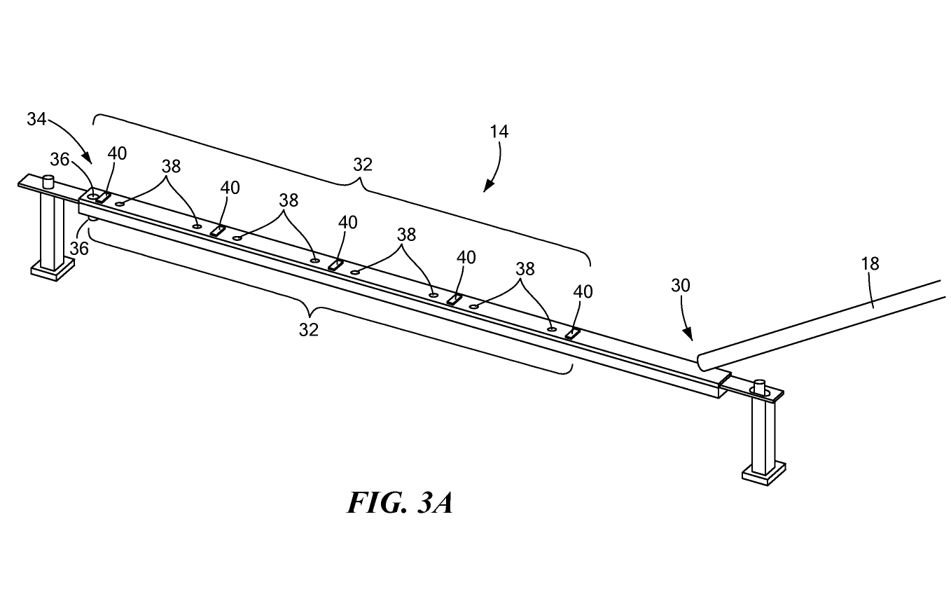

FIG. 2 also shows the above noted crucible 14, which is supported on an interior platform 28 within the housing 12 and has a substantially flat top surface. As better shown in FIG. 3A, the crucible 14 has an elongated shape with a region for growing silicon crystalline sheets 16 in a side-by-side arrangement along its length.

The crucible 14 may be considered as having three separate but contiguous regions; namely,
1) a feed region 30 (a/k/a an “introduction region 30”) for receiving silicon feedstock from the housing feed inlet 18,
2) a growth region 32 (a/k/a a “remainder region 32” or “crystal region 32”) for growing the four crystalline sheets 16, and
3) a removal region 34 for removing a portion of the molten silicon contained by the crucible 14 (i.e., to perform a dumping operation).
   In the exemplary furnace 10 shown, the removal region 34 has a outlet port 36 for removing silicon. As discussed in detail below, however, other illustrative furnaces do not have an outlet port 34 and thus, cannot perform a melt dump process.

The growth region 32 may be considered as forming four separate crystal sub-regions that each grows a single crystalline sheet 16. To that end, each crystal sub-region has a pair of filament holes 38 for respectively receiving two high temperature filaments that ultimately form the edge area of a growing silicon crystalline sheet wafer 16. Moreover, each sub-region also may be considered as being defined by a pair of optional flow control ridges 40. Accordingly, each sub-region has a pair of ridges 40 that forms its boundary, and a pair of filament holes 38 for receiving filament. These sub-regions may be referred to herein as “lanes.” As shown in the FIG. 3B, the middle crystal sub-regions share ridges 40 with adjacent crystal sub-regions. Moreover, in addition to dividing the crystal sub-regions, the ridges 40 also present some degree of fluid resistance to the flow of the molten silicon, thus providing a means for controlling fluid flow along the crucible 14.

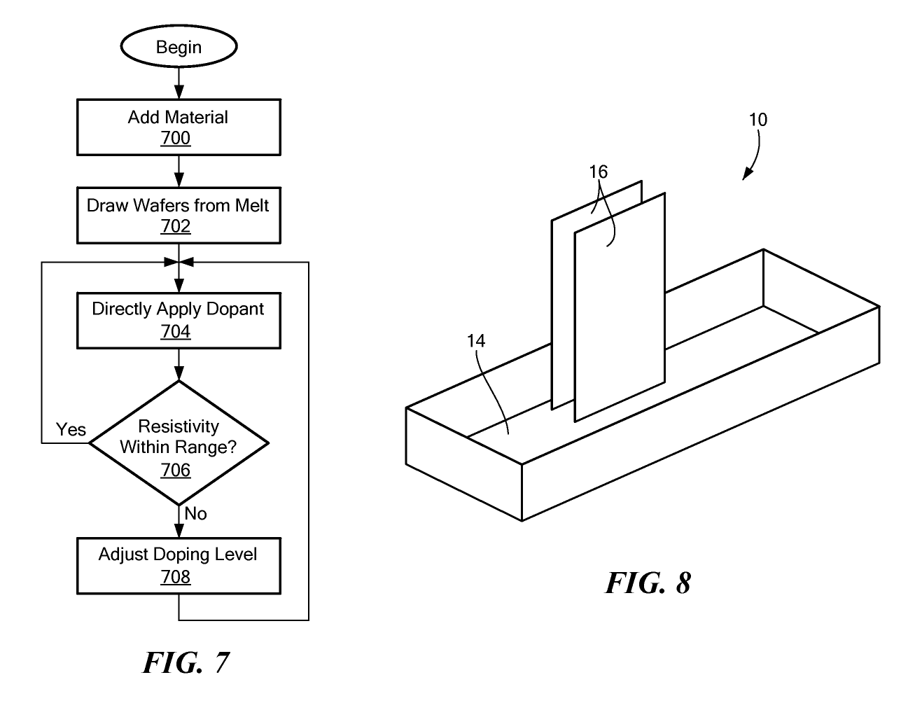

The crucible 14 should be formed from a material that can withstand high temperatures (e.g., on the order of 1400-1500 degrees C.). To that end, the crucible 14 may be formed from graphite and resistively heated to a temperature capable of maintaining silicon above its melting point. To improve unidirectional liquid flow, the crucible 14 has a length that is much greater than its width. For example, the length of the crucible 14 may be three or more times greater than its width. Of course, in other instances, the crucible 14 is not elongated in this manner. For example, the crucible 14 may have a somewhat square or rectangular shape (e.g., FIG. 8), or a nonrectangular shape.

As known by those skilled in the art and shown in FIG. 3B, continuous silicon sheet wafer growth may be carried out by introducing two filaments of high temperature material through filament holes 28 in the crucible 14. Each pair of filaments stabilizes the two edges of its growing sheet wafer 16 and, as noted above, ultimately form the edge area of its growing sheet wafer 16.

FIG. 3B schematically shows an example of a crucible 14 with shallow perimeter walls 31. In addition, this figure shows this embodiment of the crucible 14 containing liquid silicon and growing four silicon sheet wafers 16. As shown, the portion/lane of the crystal growth region 32 closest to the introduction region 30, referred to as a first growth region or lane, grows “wafer D,” while a second portion/lane of the growth region 32 grows “wafer C.” A third portion/lane of the growth region 32 grows “wafer B,” and a fourth portion/lane of the growth region 32, which is closest to the removal region 34, grows “wafer A.”

As shown in FIG. 3B, the molten silicon drawn upwardly integrates with the filament and existing frozen crystalline sheet wafers 16 just above the top surface of the molten silicon. It is at this location (known as the “liquid-solid interface”) that the solid crystalline sheet wafer 16 typically rejects a portion of the impurities from its crystalline structure. Among other things, such impurities may include iron, carbon, and tungsten. The impurities thus are rejected back into the molten silicon, consequently increasing the impurity concentration within the growth region 32. During this process, each crystalline sheet wafer 16 preferably is drawn from the molten silicon at a very low rate. For example, each crystalline sheet wafer 16 may be pulled from the molten silicon at a rate of about one inch per minute.

The crucible 14 of this embodiment is configured to cause the molten silicon to flow at a very low rate from the introduction region 30 toward the removal region 34. If this flow rate were too high, the melt region underneath the growing ribbon would be subject to high mixing forces. It is this low flow that causes a portion of the impurities within the molten silicon, including those rejected by the growing crystal wafers 16, to flow from the growth region 32 toward the removal region 34.

Several factors contribute to the flow rate of the molten silicon toward the removal region 34. Each of these factors relates to adding or removing silicon to and from the crucible 14. Specifically, a first of these factors simply is the removal of silicon caused by the physical upward movement of the filaments through the melt. For example, removal of four sheets wafers 16 at a rate of one inch per minute, where each sheet wafer 16 has a width of about three inches and a thickness ranging between about 190 microns to about 300 microns, removes about three grams of molten silicon per minute in certain sized crucibles 14. A second of these factors affecting flow rate is the selective removal/dumping of molten silicon from the removal region 34.

Consequently, to maintain a substantially constant melt height, the system adds new silicon feedstock as a function of the desired melt height in the crucible 14. To that end, among other ways, the system may detect changes in the electrical resistance of the crucible 14, which is a function of the melt it contains. Accordingly, the system may add new silicon feedstock to the crucible 14, as necessary, based upon the resistance of the crucible 14 and melt level. For example, in some implementations, the melt height may be generally maintained by adding one generally spherical silicon slug having a diameter of about a few millimeters about every one second. See, for example, the following United States patents (the disclosures of which are incorporated herein, in their entireties, by reference) for additional information relating to the addition of silicon feedstock to the crucible 14 and maintenance of a melt height: U.S. Pat. Nos. 6,090,199, 6,200,383, and 6,217,649.

The flow rate of the molten silicon within the crucible 14 therefore is caused by this generally continuous/intermittent addition and removal of silicon to and from the crucible 14. It is anticipated that at appropriately low flow rates, the geometry and shape of various forms of the crucible 14 should cause the molten silicon to flow toward the removal region 34 by means of a generally one-directional flow. By having this generally one directional flow, the substantial majority of the molten silicon (substantially all molten silicon) flows directly toward the removal region 34.

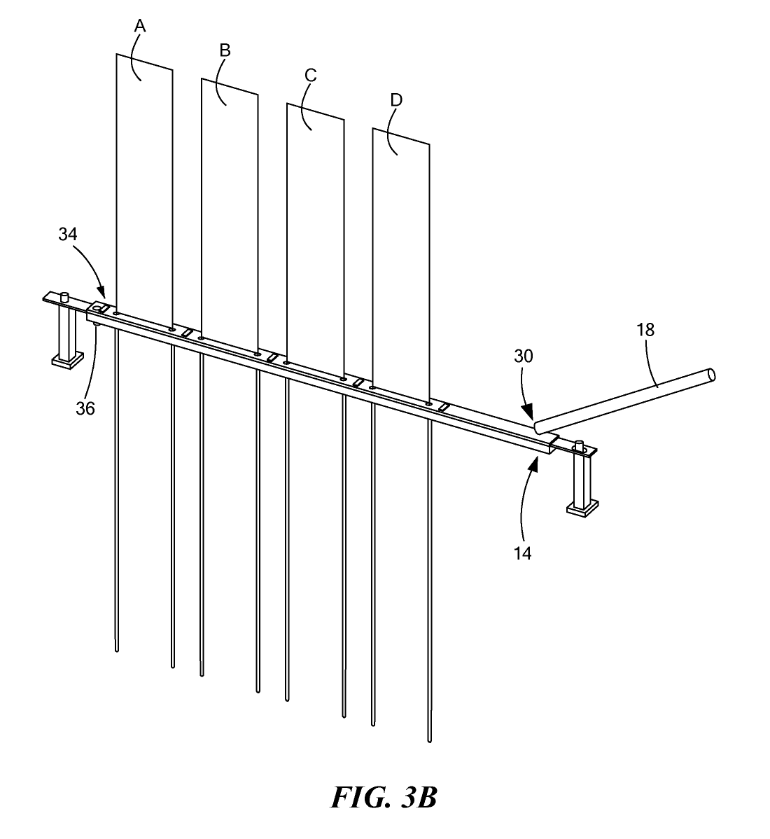

In accordance with illustrative embodiments of the invention, the furnace 10 and accompanying components shown in FIGS. 1-3B are used or modified to enable a more tightly controlled, efficient doping technique—doping by lane. FIGS. 4-8 show some such embodiments. Among other things, some embodiments for doping by lane include:
Inkjet printheads 42 that apply precise droplets to the melt,
drawing an additional filament having an dissolvable doped layer through the melt,
doping the filaments forming the edges of the sheet wafer 16, and
lowering a doped apparatus 44, such as dissolvable, doped filaments, into the melt.

FIGS. 4 through 8 detail some of these embodiments. It should be noted that these different embodiments may be used separately, or together, to finally tune the melt dopant level. In addition, these embodiments can be used with conventional doping techniques, which add doped silicon feed pellets into the melt at the feed region 30.

FIG. 4 schematically shows a first embodiment having a plurality of inkjet printheads 42 distributed about the crucible 14. As shown, each lane can have a dedicated, stationary inkjet printhead 42 filled with dopant material. In a basic embodiment, each printhead has a chamber filled with dopant, an outlet aimed generally at the melt surface, and logic for controlling the flow of dopant through the outlet. The outlet simply may be controlled to open at pre-specified intervals. Accordingly, to perform its function, the outlet may have a door, such as a moveable member of a microelectromechanical systems device (MEMS), that opens and closes at a prescribed frequency.

The number of printheads for each lane can vary depending upon the requirements and function of the furnace 10. For example, each lane could have two printheads if the melt is to be co-doped. In that case, each line could have one printhead with an n-type dopant (e.g., phosphorus) and another printhead with a p-type dopant (e.g., boron). Other co-doping embodiments may have a single printhead for each lane that has the opposite doping type to that of the melt. Alternatively, a single printhead could have a long length that extends beyond its lane. For example, this long printhead could extend across two to four lanes, and have an outlet orifice at each lane.

More complex furnaces 10 can have a single printhead that moves along a track that is generally parallel with the crucible 14. Such a printhead thus can move between the different lanes in a manner that is similar to the movement of a printhead within a conventional inkjet printer.

The inkjet printheads 42 preferably store the dopant as doped particles within the solvent, such as alcohol. For example, the dopant could comprise boron or phosphorus particles within an alcohol solution. When ejected from the outlet, the high temperature dissolves the alcohol solvent before the solvent reaches the surface of the melt. The particles, however, continue toward and into the surface of the melt, which absorbs the particles after contact.

When exposed to the high temperatures within the furnace 10, however, the solution may evaporate while within their printheads 42, consequently clogging the outlets of the printheads. This could cause catastrophic failure of the entire system. The printheads 42 thus may be spaced a sufficient distance above the crucible 14, where the temperatures are much lower. When spaced far from the crucible 14, however, the dopant may not precisely fall into the melt.

To mitigate this problem, illustrative embodiments may include steerable dopant particles within the solvent. Specifically, the particles could be loaded into the inkjet printheads 42 a the known polarization, i.e., they have a charge. The furnace 10 thus may have electronics and electrodes that generate a controllable electric field near the crucible 14 to steer the doped particles into the melt. The strength and extent of the electric field can be selected based upon a number of parameters, including the position of the printheads 42, the charge of the particles, and the anticipated convective currents within the furnace 10.

In addition to using charged particles, or instead of using charged particles, some embodiments form a heat insulating shield (not shown) in front of the printheads. Of course, the shield should have an opening for each printhead opening. In some embodiments, the shield opening opens only when ejecting dopant, thus further controlling the heat profile behind it. Alternatively, the shields could be integrated into the printheads.

Doping of each lane can be independently controlled on the fly, or through programming, depending upon its requirements. For example, if some of the lanes are co-doped, those lanes near the dump outlet 34 may receive more co-dopant than those near the inlet 18. In any case, as an example, known inkjet printheads 42 should be able to deliver droplets at greater than 1000 hertz in very repeatable, precise droplet sizes. Of course, inkjet printheads 42 can deliver droplets at different rates.

As noted above with respect to FIG. 2, the furnace 10 also has the feedback system 22 (i.e., the resistance detector 24 and controller 26) for controllably doping each lane. Accordingly, the resistance detectors 24 may continuously or periodically check the resistance of the growing sheet wafers 16. If the resistance of any one of the sheet wafers 16 is outside of a prescribed range, then the controller 26 can forward a signal to the corresponding printhead to adjust its dopant level. The signal preferably uses a hardwired connection, although a wireless connection also may suffice.

For example, in a furnace 10 implementing co-doping with a primarily p-type doped melt, if the wafer 16 in the lane nearest the outlet port 36 has a resistance indicating too much p-type doping, then the controller 26 may signal its corresponding printhead 42 to deposit more n-type dopant into the melt in that lane. Alternatively, or in addition, the controller 26 may signal its corresponding printhead to deposit less p-type dopant into the melt. In a similar manner, for a furnace 10 that does not co-dope the melt, the controller 26 simply may signal its corresponding printhead 42 to deposit less p-type dopant into the melt.

Rather than using printheads 42, or in addition to using printheads 42, some embodiments use the filaments forming the outside edges of the wafer 16 to dope the melt directly in some or all of the lanes. To that end, the outside surface of some or all of the filaments may be coated with prescribed dopants.

Those skilled in the art can use any combination of the coated filaments to dope the melt. For example, certain lanes may have filaments doped with one type of dopant (e.g., boron), while other lanes may have filaments doped with the other kind of dopant (e.g., phosphorous). In fact, some lanes could use filaments with opposite doping characteristics, i.e., one filament could be doped with an n-type dopant, while the other filament could be doped with a p-type dopant. Moreover, different filaments can have different dopant concentrations to further fine tune the dopant level of the melt in each lane. For example, in a p-type doped melt, in a given lane, the filament nearer the introduction region 30 could have a p-type doping that is greater than that of the filament farther downstream.

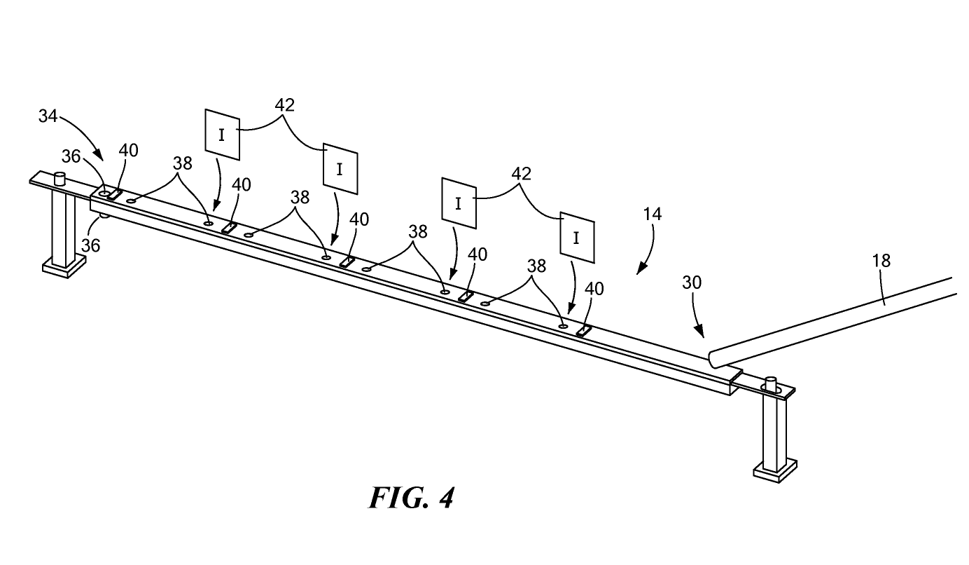

Another embodiment passes a filament with dopant on its outside surface directly through prescribe locations of the melt. FIG. 5 shows one such embodiment having additional filament holes 46 through the crucible 14 for passing these additional doped filaments generally perpendicular to the surface of the melt. The puller system 20 or pushing devices should suffice to move the filaments through the melt. Some embodiments use conventional filaments, such as those used to form the sheet wafers 16. Alternative embodiments, however, may use other types of filaments, such as filaments that partially or fully dissolve in the melt. In fact, these additional filaments may be formed from materials that are completely different than those used to form the filaments passing through the primary holes 28.

Unlike the filaments used to form the edges of the sheet wafers 16, the controller 26 or other control apparatus can pass these filaments through the melt at varying rates. For example, if the sheet wafer resistance is within the prescribed range for a melt having these filaments as their only source of dopant, then the controller 26 may pass these filaments at prescribed rates. These filaments can pass through the melt at an increased or decreased rates, however, if the resistance is outside of the prescribed range.

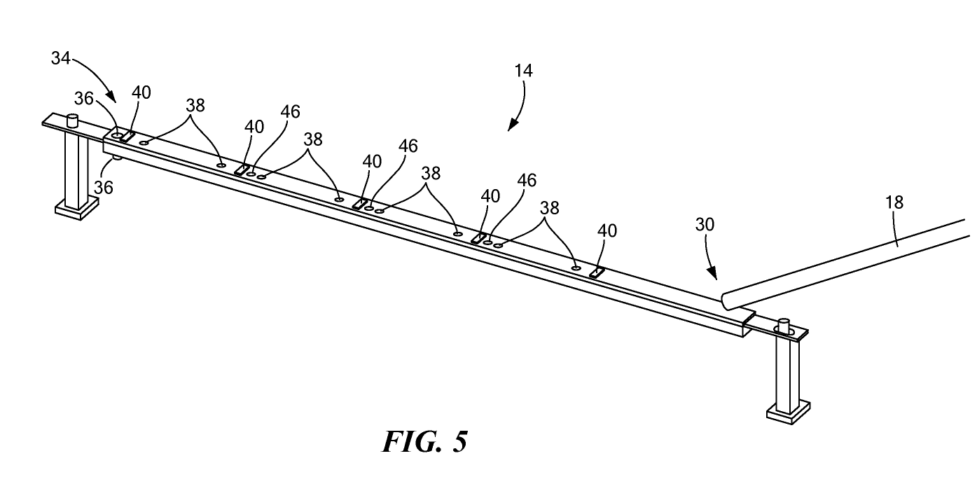

Other embodiments, such as that shown in FIG. 6, directly contact of the top surface of the melt with a doped apparatus 44 at specific points of the crucible 14. Unlike the embodiments shown in FIG. 5, the doped apparatus 44 in this embodiment enters the melt from the top melt surface and not through the bottom of the crucible 14. Thus, the doped apparatus 44 can be lowered into the melt from the top or side of the crucible 14.

Among other things, the doped apparatus 44 may include a doped/coated filament, wire, plug, highly doped piece of silicon, or other apparatus that can be retracted or extended into the melt. Moreover, the doped apparatus 44 of this embodiment preferably partially or completely dissolves after contact with the melt, although some embodiments do not dissolve. After contact with the melt, some embodiments may remove or retract the doped apparatus 44 from the crucible 14 after substantially all of its dopant diffuses into the melt, or if no further doping is necessary. If the doped apparatus 44 still has dopant, it can be reintroduced into the melt at a later time.

Accordingly, in a manner similar to the embodiments discussed above with respect to FIG. 5, the doped apparatus 44 can be added to the melt at any rate necessitated by the system requirements. More specifically, the feedback system 22 may control the rate at which this dopant is applied to the melt. If more dopant is required, then the furnace 10 can lower the doped apparatus 44 into the melt at a faster rate (depending on the rate that the doped apparatus 44 dissolves or the rate that the dopant dissolves). As noted, the doped apparatus 44 can be removed completely from the melt when more dopant is not needed.

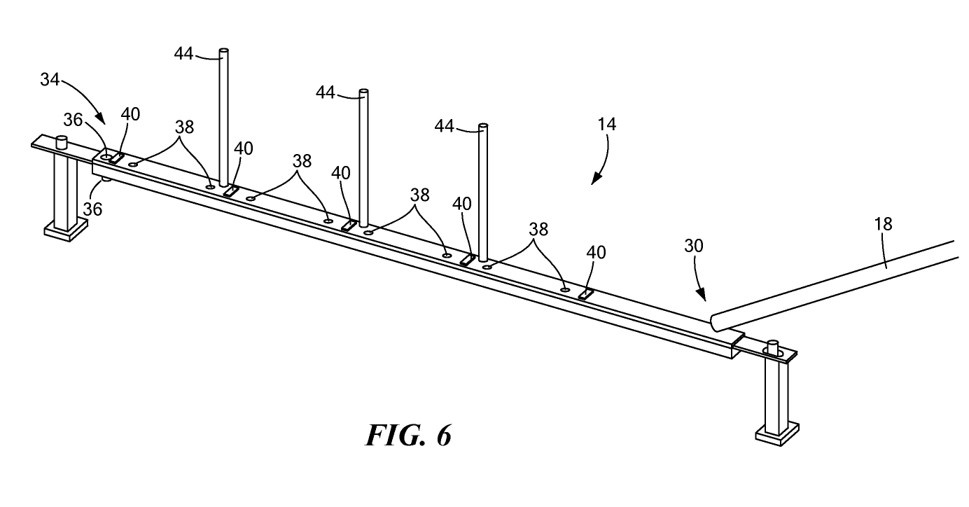

FIG. 7 shows a process of forming sheet wafers 16 while independently controlling the doping of the various lanes in the crucible 14. It should be noted that for simplicity, this described process is a significantly simplified version of an actual process used to form a plurality of doped sheet wafers 16 in parallel. Accordingly, those skilled in the art would understand that the process may have additional steps not explicitly shown in FIG. 7. Moreover, some of the steps may be performed in a different order than that shown, or at substantially the same time. Those skilled in the art should be capable of modifying the process to suit their particular requirements.

The process begins at step 700, which adds material to the crucible 14. As noted above, silicon or other material may be added to the crucible 14 in a prescribed manner through its introduction region 30. The silicon may be doped or undoped, depending on the doping techniques used downstream. The high temperatures of the crucible 14 and internal environment melt the material into a liquid/molten form.

Next, step 702 draws the four sheet wafers 16 from the melt at substantially the same time. To that end, several pairs of filaments are passed through the crucible 14, which contains the molten silicon. In illustrative embodiments, the filaments are spaced more than about 145 millimeters apart. For example, the filaments may be spaced about 155 or about 156 millimeters apart. Alternative embodiments can space the filaments closer together or farther apart. In any event, drawing the filaments from the melt in this manner causes the filament sheet wafers 16 to grow out of the housing 12, as shown in FIG. 1.

At the same time, or at a later time, the process directly applies dopant to one or more lanes of the growth region 32 (step 704). Specifically, illustrative embodiments do not begin drawing wafers 16 as required by step 702 until the melt is appropriately doped. Accordingly, in embodiments using pellets coated with dopant, the pullers of the puller system 20 can begin drawing the wafers 16 as soon as the melt reaches an appropriate volume within the crucible 14. The embodiments using pellets not coated with dopant, however, should not begin drawing the wafers 16 from the melt until it is appropriately doped.

Accordingly, various embodiments directly dope specific lanes, thus bypassing the introduction region 30 (i.e., this dopant is not directly added to the introduction region 30—other dopant can be added to the introduction region 30, but this dopant bypasses that region 30 as it is added to the specific lanes of the crucible 14). For example, the embodiment of FIG. 4 may cause specific printheads 42 to begin ejecting dopant into the certain lanes, while not ejecting dopant into other lanes. As a second example, the embodiment of FIG. 6 may directly apply dissolvable filaments into zero, one or more lanes, thus also bypassing the introduction region 30. Accordingly, step 704 enables the furnace 10 to independently dope the lanes of the crucible 14.

Of course, illustrative embodiments ensure that the dopant levels remain within tight constraints, which produces the most efficient sheet wafers 16. To that end, the resistance detectors 24 then determine if the resistivity of each of the wafers 16 is within the prescribed limits noted above (step 706). If not at the appropriate levels, then step 708 adjusts the doping levels accordingly.

For example, if the melt at the lane in question has too much P-doping, then the controller 26 may stop applying p-dopant into that lane. Moreover, as known by those in the art, the dopant in the melt diffuses to other lanes (or even into the introduction region 30), which then impacts the doping level in other lanes. Accordingly, if the dopant level at a given lane is too high, then the process may reduce the dopant in an upstream lane. Those skilled in the art should calibrate the system to compensate for the impact not only on the lane in question, but the impact on other lanes of the crucible 14.

This process thus enables a number of permutations to the process of doping the melt. Among others, the process can dope the melt with coated silicon pellets added to the introduction region 30 (i.e., this dopant material bypassing the growth region 32) and with dopant applied directly to one or more of the lanes in the growth region 32 (this other dopant material bypassing the introduction region 30). The process also can dope the melt by doping specific lanes in the growth region 32 only.

As noted above, various embodiments apply to other furnace configurations. For example, FIG. 8 schematically shows an alternative furnace configuration that draws the sheet wafers 16 from the melt in a manner where the wafers 16 face each other. Other embodiments may draw the wafers 16 from the melt in a staggered or some other orientation relative to each other.

Illustrative embodiments therefore permit fine tuned doping levels, thus producing better quality sheet wafers 16. Moreover, various embodiments facilitate co-doping. In either case, such embodiments should produce fewer rejected wafers 16, thus improving wafer yields—and reducing costs.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a sheet wafer, the method comprising:
adding material to a crucible having a feed area and a remaining area, the material being added to the feed area;
melting the material to form a first growth area and a second growth area, the remaining area including the first and second growth areas;
drawing a first sheet wafer from the first growth area;
drawing a second sheet wafer from the second growth area while drawing the first sheet wafer from the first growth area; and
directly applying dopant to the material at the remaining area, the dopant bypassing the feed area to dope at least a portion of the remaining area.

2. The method as defined by claim 1 further comprising directly applying dopant to material in the feed area of the crucible, directly applying dopant to material in the feed area comprising bypassing the remaining area to dope the feed area.

3. The method as defined by claim 1 wherein directly applying comprises directly applying dopant to the second growth area and not directly applying dopant to the first growth area, the first growth area being between the feed area and the second growth area, the directly applied dopant diffusing to the first growth area from the second growth area.

4. The method as defined by claim 1 wherein directly applying comprises directly applying dopant to the first growth area and the second growth area, the first growth area being between the feed area and the second growth area.

5. The method as defined by claim 1 wherein the directly applied dopant diffuses dopant to material in the feed area.

6. The method as defined by claim 1 wherein directly applying comprises directly contacting a doped apparatus into the material in the remaining area.

7. The method as defined by claim 6 wherein the doped apparatus comprises a filament, the filament substantially disintegrating after contacting the material to release the dopant.

8. The method as defined by claim 1 wherein directly applying comprises releasing doped particles from an inkjet apparatus into one or more prespecified portions of the remaining area.

9. The method as defined by claim 1 wherein drawing a first sheet wafer comprises passing a pair of filaments through the material, at least one of the filaments having a coating of dopant, the dopant from the at least one filament being a source for directly applying dopant to the material at the remaining area.

10. The method as defined by claim 1 wherein directly applying comprises passing a member through the material in the remaining area.

11. The method as defined by claim 1 further comprising measuring a quality of at least one of the first and second sheet wafers, directly applying dopant being a function of the measured quality.

12. The method as defined by claim 11 wherein the quality is the resistivity of the at least one of the first and second sheet wafers, the method changing the volume of dopant directly applied as a function of the resistivity.

13. The method as defined by claim 1 further comprising drawing at least one other sheet wafer from the material in the crucible, each of the other sheet wafers being drawn from separate growth regions.

14. The method as defined by claim 1 wherein the first and second wafers are positioned in a side-by-side manner.

15. The method as defined by claim 1 wherein the first and second wafers are positioned to face each other.

16. An apparatus for forming a plurality of sheet wafers, the apparatus comprising:
a crucible having a feed area and a remaining area;
a material inlet for receiving material to be added to the feed area of the crucible;
a wafer puller for drawing a plurality of sheet wafers from the remaining area; and
a doping apparatus operably coupled with the crucible, the doping apparatus being configured to directly add dopant to the remaining area, the doping apparatus bypassing the feed area.

17. The apparatus as defined by claim 16 wherein the doping apparatus includes an inkjet apparatus.

18. The apparatus as defined by claim 16 wherein the doping apparatus comprises an applier operably coupled with the crucible, the applier being configured to move a doped component into the remaining area to dope the remaining area.

19. The apparatus as defined by claim 16 further comprising a remaining area inlet for receiving doped material directly in the remaining area.

20. The apparatus as defined by claim 16 wherein the remaining area comprises a first growth area and a second growth area, the first growth area having a pair of growth filament openings for receiving filaments for growing a first sheet wafer, the first growth area also have at least one doping filament opening for receiving a doped filament.

21. The apparatus as defined by claim 16 further having a resistance detector for measuring resistance through at least one sheet wafer, the apparatus further having a controller for controlling dopant into the remaining area as a function of the resistance measurement.

22. The apparatus as defined by claim 16 wherein the remaining area includes a first growth region and a second growth region, the doping apparatus being configured to apply dopant to one or both of the first and second growth regions.

23. The apparatus as defined by claim 22 wherein the remaining area includes a third growth region, the doping apparatus being configured to apply dopant to one, two, or all of the first, second and third growth regions.

24. A method of forming a sheet wafer, the method comprising:
adding material to a crucible having a feed area and a dump area, the material being added to the feed area and being removed through the dump area;
melting the material to form a wafer growth area between the feed area and the dump area;
substantially simultaneously drawing a plurality of sheet wafers from the growth area; and
directly applying dopant to the melted material at the growth area, the dopant bypassing the feed area to dope at least a portion of the growth area.

25. The method as defined by claim 24 wherein the directly applied dopant diffuses from the growth area and into the feed area.

26. The method as defined by claim 24 wherein the crucible has a length, the plurality of sheet wafers are positioned along the length of the crucible.

27. The method as defined by claim 24 wherein the material comprises silicon.

28. The method as defined by claim 24 further comprising directly applying dopant to material in the feed area of the crucible, directly applying comprising bypassing the growth area to dope the feed area.

29. The method as defined by claim 24 wherein directly applying comprises directly contacting a doped apparatus into the material in the growth area.

30. The method as defined by claim 29 wherein the doped apparatus comprises a filament, the filament substantially disintegrating after contacting the material to release the dopant.

31. The method as defined by claim 24 wherein directly applying comprises releasing doped particles from an inkjet apparatus into one or more prespecified portions of the growth area.

32. The method as defined by claim 24 further comprising measuring a quality of at least one of the plurality of sheet wafers, directly applying dopant being a function of the measured quality.

33. The method as defined by claim 32 wherein the quality is the resistivity of the at least one of the plurality of sheet wafers, the method changing the volume of dopant directly applied as a function of the resistivity.
